(19) United States
(12) Patent Application Publication
(10) Pub. No.: US 2025/0140576 A1
(43) Pub. Date: May 1, 2025

(54) SUBSTRATE PROCESSING METHOD, MANUFACTURING METHOD, AND SUBSTRATE PROCESSING APPARATUS

(71) Applicant: SEMES CO., LTD., Cheonan-si (KR)

(72) Inventors: Jun Hee CHOI, Yongin-si (KR); Tae Keun KIM, Siheung-si (KR); Kang Sul KIM, Hwaseong-si (KR); Kyeong Min LEE, Hwaseong-si (KR); Yong Jun KIM, Anyang-si (KR); Hyeong Soo PARK, Yongin-si (KR)

(73) Assignee: SEMES CO., LTD., Cheonan-si (KR)

(21) Appl. No.: 18/921,283

(22) Filed: Oct. 21, 2024

(30) Foreign Application Priority Data
Oct. 27, 2023 (KR) 10-2023-0145866

(51) Int. Cl. H01L 21/67; H01L 21/02; H01L 21/304

(52) U.S. Cl. CPC H01L 21/67034; H01L 21/02057; H01L 21/304; H01L 21/67051

(57) ABSTRACT

Disclosed is a method of processing a substrate, the method including: a coating operation of supplying a coating liquid containing a volatile component to a top surface of the substrate to form a cleaning film; and a cleaning film processing operation of processing the cleaning film, in which the cleaning film processing operation includes: a crack formation operation of generating a crack in the cleaning film formed on the substrate to form film flakes; and a delamination operation of delaminating the film flakes from the top surface of the substrate by volatilizing the volatile component contained in the film flake.

### CROSS-REFERENCE TO RELATED APPLICATIONS

This application claims priority to and the benefit of Korean Patent Application No. 10-2023-0145866 filed in the Korean Intellectual Property Office on Oct. 27, 2023, the entire contents of which are incorporated herein by reference.

### TECHNICAL FIELD

The present invention relates to a substrate processing method, a manufacturing method, and a substrate processing apparatus, and more particularly to a substrate processing method a substrate processing apparatus, and a manufacturing method of a semiconductor device for manufacturing a semiconductor device.

### BACKGROUND ART

To manufacture semiconductor devices, various processes are performed on wafers, such as photography, deposition, ashing, etching, and ion implantation. Before and after these processes, a cleaning process is performed to clean particles that remain on the wafer. The cleaning process is accomplished by supplying a cleaning solution to the substrate supported on the spin head.

In recent years, as the cleaning requirements for particles adhering to wafers have increased, various methods have been considered to further improve the removal efficiency of particles adhering to wafers. As the linewidth of the patterns formed on the wafers becomes progressively smaller, particles that exist between the patterns may be difficult to be removed from the wafers by simply supplying a cleaning solution to the wafers. Also, depending on the particles, the particles may strongly adhere to the wafer and be difficult to be removed from the wafer.

Recently, in order to solve the above problems, a method of cleaning a wafer by supplying a coating liquid containing a polymer onto a wafer, curing or solidifying the coating liquid to form a cleaning film, and removing the formed cleaning film has been considered.

In the case of removing particles by forming a cleaning film, the process of curing or solidifying the coating liquid causes the treatment solution to phase change into the cleaning film with particles captured. Then, to delaminate the formed cleaning film from the wafer, a delamination liquid, such as deionized water, is supplied to the rotating wafer. The delamination liquid splits the cleaning film to form film flakes, penetrates between the formed film flakes, and delaminates the film flakes from the wafer. Then, to rinse the wafers, a rinse liquid, such as IPA, is supplied to the rotating wafers. The wafers are then dried as needed.

The most important operation is to delaminate the cleaning film from the wafer by supplying deionized water. However, it is time-consuming to supply deionized water to a rotating wafer to delaminate the cleaning film.

When the cleaning film is a component that is easily soluble in deionized water, the deionized water dissolves the cleaning film without forming film flakes, so the cleaning film is provided with a component that is soluble in deionized water but not dissolved too quickly by deionized water. Thus, deionized water may take a long time to form film flakes.

In addition, the surface of the wafer may be hydrophobized or hydrophilized as needed. In the case of hydrophobized wafers, even when film flakes may be formed from the cleaning film when deionized water is supplied, it may be difficult for the deionized water to penetrate between the film flakes and the top surface of the substrate, making it difficult to properly delaminate the film.

These issues are illustrated by the experimental data in FIG. 1. In FIGS. 1, 1 and 2 on the x-axis denote the experimental round, and PRE denotes the particle removal efficiency. When wafers are cleaned by using a cleaning film as described above, it may be seen that the particle removal efficiency for hydrophobized wafers is significantly lower than hydrophilized or untreated wafers.

### SUMMARY OF THE INVENTION

The present invention has been made in an effort to provide a substrate processing method, a manufacturing method, and a substrate processing apparatus that are capable of efficiently cleaning a substrate.

The present invention has also been made in an effort to provide a substrate processing method, a manufacturing method, and a substrate processing apparatus that may form a film flake from a cleaning film formed on a substrate and effectively delaminate the film flake from a top surface of the substrate.

The present invention has also been made in an effort to provide a substrate processing method, a manufacturing method, and a substrate processing apparatus that are capable of processing a cleaning film formed on a substrate by using a gas phase fluid rather than a liquid phase fluid.

The present invention has been made in an effort to provide a substrate processing method, a manufacturing method, and a substrate processing apparatus that are capable of effectively shortening the time required to process a cleaning film.

The object of the present invention is not limited thereto, and other objects not mentioned will be clearly understood by those of ordinary skill in the art from the following description.

An exemplary embodiment of the present invention provides a method of processing a substrate, the method including: a coating operation of supplying a coating liquid containing a volatile component to a top surface of the substrate to form a cleaning film; and a cleaning film processing operation of processing the cleaning film, in which the cleaning film processing operation includes: a crack formation operation of generating a crack in the cleaning film formed on the substrate to form film flakes; and a delamination operation of delaminating the film flakes from the top surface of the substrate by volatilizing the volatile component contained in the film flake

According to the exemplary embodiment, the crack formation operation may include spraying humidified air to increase humidity of a space above the substrate.

According to the exemplary embodiment, in the coating operation and the crack formation operation, the humidity of the space above the substrate may be kept the same, the coating operation may include rotating the substrate, and the crack formation operation may include stopping the rotation of the substrate.

According to the exemplary embodiment, the delamination operation may include heating the substrate to volatilize the volatile component contained in the film flake.

According to the exemplary embodiment, the heating of the substrate may be accomplished by a heater provided in a chuck supporting the substrate.

According to the exemplary embodiment, the heating of the substrate may be accomplished by supplying heated pure water to a bottom surface of the substrate.

According to the exemplary embodiment, the delamination operation may include spraying dry air to reduce humidity in the space above the substrate to volatilize the volatile component contained in the film flake.

According to the exemplary embodiment, the spraying of the dry air may be accomplished by supplying, by a drying nozzle, dry gas from an upper side of the substrate.

According to the exemplary embodiment, the spraying of the dry gas may be accomplished by forming a dried downflow in the interior space by a downflow unit coupled to a housing providing an interior space in which the substrate is processed.

According to the exemplary embodiment, in the coating operation, the substrate may be in a rotating state in which the substrate is rotated, and in the cleaning film processing operation, the substrate may be in a non-rotating state in which the substrate is not rotated.

According to the exemplary embodiment, the method may further include, after the cleaning film processing operation, a rinsing operation of supplying a rinse liquid to the rotating substrate while dissolving the film flakes.

According to the exemplary embodiment, in the rinse operation, the substrate may be rotated at a speed of 500 to 1000 RPM.

According to the exemplary embodiment, the rinse liquid may be isopropyl alcohol.

According to the exemplary embodiment, the cleaning film processing operation may be performed in a state where the space above the substrate is covered by a cover disposed on an upper side of the substrate.

Another exemplary embodiment of the present invention provides a manufacturing method including: a coating operation of supplying a coating liquid containing a volatile component, a first component, and a second component to a top surface of a rotating substrate to form a cleaning film; and a crack formation operation of regulating humidity around the non-rotating substrate to generate cracks in the cleaning film and form film flakes.

According to the exemplary embodiment, the crack formation operation may include regulating humidity in a space above the substrate to be larger than in the coating operation. According to the exemplary embodiment, the first component may be a component that is more soluble in moisture surrounding the substrate than the second component.

According to the exemplary embodiment, the first component may be organic acid and the second component may be a polymer.

According to the exemplary embodiment, the manufacturing method may further include a delamination operation of delaminating the film flakes from the top surface of the substrate by volatilizing the volatile component contained in the film flake.

Still another exemplary embodiment of the present invention provides an apparatus for processing a substrate, the apparatus including: a housing providing an interior space; a substrate support unit for supporting and rotating a substrate in the interior space; a supply unit for supplying a fluid processing the substrate supported by the substrate support unit; a humidity regulating device for regulating humidity in the interior space; and a controller, in which the supply unit includes: a first nozzle for supplying a coating liquid containing a volatile component to a substrate supported on the substrate support unit; a second nozzle for supplying a rinse liquid to the substrate supported on the substrate support unit; and a drying nozzle for spraying dry gas to the substrate placed on the substrate support unit, and the controller controls the substrate support unit and the supply unit so that the substrate support unit rotates the substrate, and the first nozzle supplies a coating liquid to the rotating substrate to form a cleaning film; controls the humidity regulating device and the substrate support unit so that the substrate support unit so that film flakes are formed by generating cracks in the cleaning film while the substrate support unit stops rotating the supported substrate and spray humidified air into the interior space to generate the cracks in the cleaning film; and controls the supply unit to spray the dry gas to volatilize the volatile components contained in the film flakes so that the film flakes are delaminated from the substrate.

According to one exemplary embodiment of the present invention, the substrate may be cleaned efficiently.

Further, according to one exemplary embodiment of the present invention, a film flake may be formed from the cleaning film formed on the substrate, and the film flake may be effectively delaminated from the top surface of the substrate.

Furthermore, according to one exemplary embodiment of the present invention, the cleaning film formed on the substrate may be treated by using a gas phase fluid rather than a liquid phase fluid.

Furthermore, according to one exemplary embodiment of the present invention, the time required to process the cleaning film may be effectively reduced.

The effect of the present invention is not limited to the foregoing effects, and those skilled in the art may clearly understand non-mentioned effects from the present specification and the accompanying drawings.

### BRIEF DESCRIPTION OF THE DRAWINGS

FIG. 1 is a graph illustrating particle removal efficiency of cleaning a wafer using a cleaning film, depending on whether a surface of the wafer is treated or not.

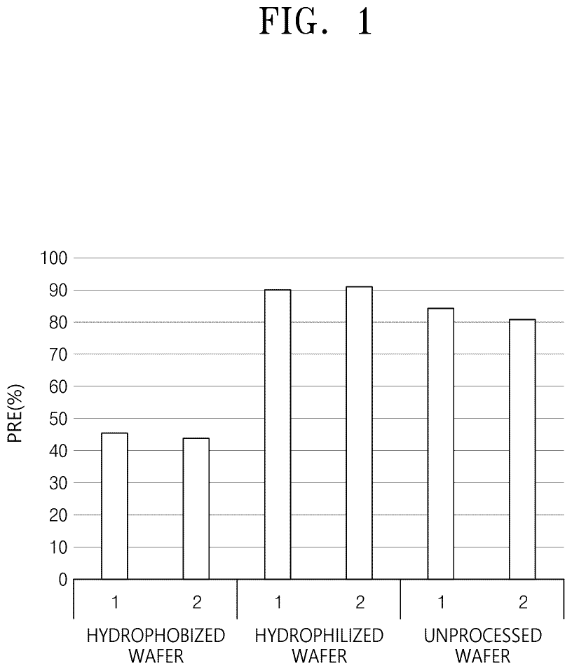

FIG. 2 is a top plan view of a substrate processing apparatus according to an exemplary embodiment of the present invention.

FIG. 3 is diagram illustrating a substrate processing apparatus provided in a process chamber of FIG. 2.

FIG. 4 is a flow chart illustrating a substrate processing method according to an exemplary embodiment of the present invention.

FIG. 5 is a diagram illustrating the substrate processing apparatus performing a coating operation of FIG. 4.

FIG. 6 is an enlarged view of a portion of a top surface of the substrate when performing the coating operation of FIG. 4.

FIG. 7 is a diagram illustrating the substrate processing apparatus performing a crack formation operation of FIG. 4.

FIG. 8 is an enlarged view of a portion of the top surface of the substrate when performing the crack formation operation of FIG. 4.

FIG. 9 is a diagram illustrating the substrate processing apparatus performing a delamination operation of FIG. 4.

FIG. 10 is an enlarged view of a portion of the top surface of the substrate when performing the delamination operation of FIG. 4.

FIG. 11 is a diagram illustrating the substrate processing apparatus performing a rinse operation of FIG. 4.

FIG. 12 is an enlarged view of a portion of the top surface of the substrate when performing the rinse operation of FIG. 4.

FIG. 13 is a diagram illustrating another view of the substrate processing apparatus performing the delamination operation of FIG. 4.

FIG. 14 is a diagram illustrating another view of the substrate processing apparatus performing the delamination operation of FIG. 4.

FIG. 15 is a diagram illustrating a substrate processing apparatus according to another exemplary embodiment of the present invention.

FIG. 16 is a diagram illustrating the substrate processing apparatus of FIG. 15 performing the crack formation operation.

FIG. 17 is a diagram illustrating the substrate processing apparatus of FIG. 15 performing the delamination operation.

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., +10%).

When the terms “about” or “substantially” are used in connection with a numerical value, it should be understood that the associated numerical value includes a manufacturing or operational tolerance (e.g., +10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

A substrate W described herein may be a wafer. The substrate W described herein is a patterned wafer, for example. However, without limitation, the substrate W may be provided in various shapes that require a cleaning process.

Further, a substrate processing method described herein may be a method of processing a wafer for manufacturing a semiconductor device. Further, a substrate processing method described herein may be a substrate cleaning method of cleaning a substrate W performed to manufacture a semiconductor device. Further, a substrate processing apparatus described herein may be an apparatus for processing a wafer for manufacturing a semiconductor device.

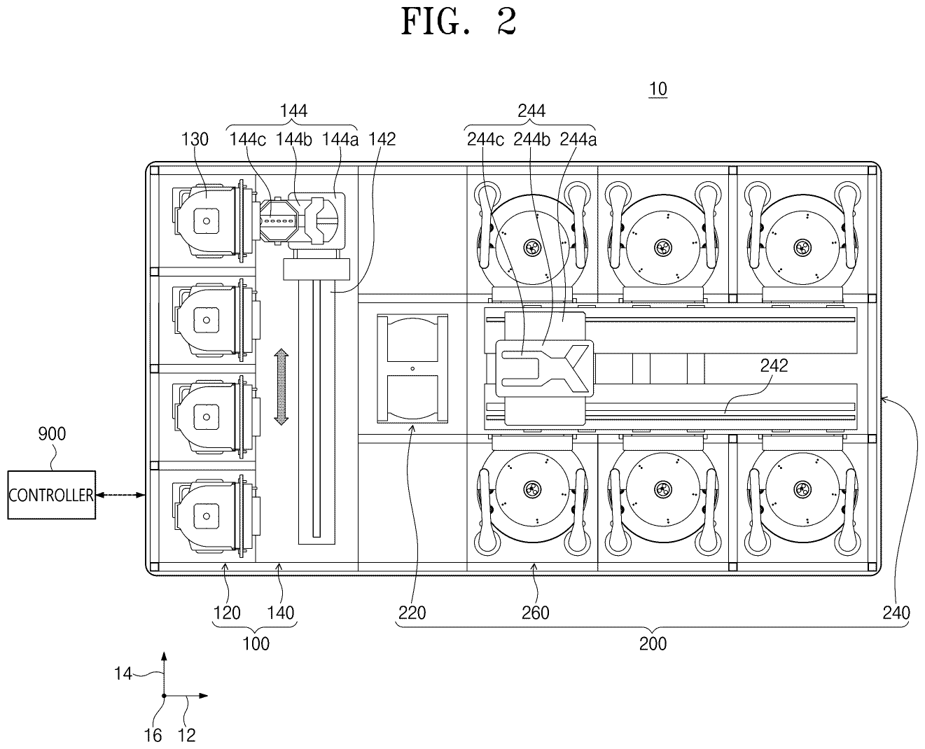

Hereinafter, exemplary embodiments of the present invention will be described in detail with reference to FIGS. 2 to 17.

FIG. 2 is a top plan view of a substrate processing apparatus according to an exemplary embodiment of the present invention.

Referring to FIG. 2, a substrate processing apparatus 10 includes an index module 100, a process processing module 200, and a controller 900. The Index module 100 includes a load port 120 and a transfer frame 140. The load port 120, the transfer frame 140, and the process processing module 20 are arranged in sequential rows. Hereinafter, a direction in which the load port 120, the transfer frame 140, and the process processing module 200 are arranged is referred to as a first direction 12, a direction perpendicular to the first direction 12 when viewed from above is referred to as a second direction 14, and a direction perpendicular to a plane including the first direction 12 and the second direction 14 is referred to as a third direction 16.

A carrier 130 in which a substrate W is accommodated is seated on the load port 120. A plurality of load ports 120 is provided and is arranged in a line along the second direction 14. The number of load ports 120 may be increased or decreased depending on process efficiency and footprint requirements of the process processing module 200. The carrier 130 is formed with a plurality of slots (not illustrated) for receiving the substrates W in a horizontal position relative to the ground. As the carrier 130, a Front Opening Unified Pod (FOUP) may be used.

The process processing module 200 includes a buffer unit 220, a transfer chamber 240, and a process chamber 260. The transfer chamber 240 may disposed so that a longitudinal direction thereof is parallel to the first direction. The process chambers 260 may be disposed at opposite sides of the transfer chamber 240. On one side of the transfer chamber 240 and on the other side of the transfer chamber 240, the process chambers 260 are provided to be symmetrical with respect to the transfer chamber 240. On one side of the transfer chamber 240, a plurality of process chambers 260 are provided. Some of the process chambers 260 may be disposed in the longitudinal direction of the transfer chamber 240. Further, some of the plurality of process chambers 260 may be disposed to be stacked on each other. That is, the plurality of process chambers 260 may be disposed in an arrangement of A×B at one side of the transfer chamber 240. Here, A is the number of process chambers 260 provided in a line along the first direction 12, and B is the number of process chambers 260 provided in a line along the third direction 16. When four or six process chambers 260 are provided at one side of the transfer chamber 240, the process chambers 260 may be disposed in an arrangement of 2×2 or 3×2. The number of process chambers 260 may be increased or decreased. Unlike the foregoing, the process chamber 260 may be provided only to one side of the transfer chamber 240. In addition, the process chamber 260 may be provided as a single layer on one side and both sides of the transfer chamber 240.

The buffer unit 220 is disposed between the transfer frame 140 and the transfer chamber 240. The buffer unit 220 may provide a space in which the substrate W stays before the substrate W is transferred between the transfer chamber 240 and the transfer frame 140. A slot (not illustrated) in which the substrate W is placed is provided inside the buffer unit 220. A plurality of slots (not illustrated) is provided so as to be spaced apart from each other in the third direction 16. A surface of the buffer unit 220 facing the transfer frame 140 and a surface of the buffer unit 220 facing the transfer chamber 240 may be opened.

The transfer frame 140 transfers the substrate W between the carrier 130 seated at the load port 120 and the buffer unit 220. An index rail 142 and an index robot 144 are provided to the transfer frame 140. A longitudinal direction of the index rail 142 is provided to be parallel to the second direction 14. The index robot 144 is installed on the index rail 142, and linearly moves in the second direction 14 along the index rail 142. The index robot 144 includes a base 144a, a body 144b, and an index arm 144c. The base 144a is installed to be movable along the index rail 142. The body 144b is coupled to the base 144a. The body 144b is provided to be movable in the third direction 16 on the base 144a. Further, the body 144b is provided to be rotatable on the base 144a. The index arm 144c is coupled to the body 144b and is provided to be movable forwardly and backwardly with respect to the body 144b. A plurality of index arms 144c is provided to be individually driven. The index arms 144c are disposed to be stacked in the state of being spaced apart from each other in the third direction 16. Some of the index arms 144c may be used when the substrate W is transferred from the process processing module 20 to the carrier 130, and another some of the plurality of index arms 144c may be used when the substrate W is transferred from the carrier 130 to the process processing module 200. This may prevent particles generated from the substrate W before the process processing from being attached to the substrate W after the process processing in the process of loading and unloading the substrate W by the index robot 144.

The transfer chamber 2400 transfers the substrate W between the buffer unit 2200 and the process chamber 260, and between the process chambers 260. A guide rail 242 and a main robot 244 are provided to the transfer chamber 240. The guide rail 242 is disposed so that a longitudinal direction thereof is parallel to the first direction 12. The main robot 244 is installed on the guide rail 242 and linearly moved along the first direction 12 on the guide rail 242. The main robot 244 includes a base 244a, a body 244b, and a main arm 244c. The base 244a is installed to be movable along the guide rail 242. The body 244b is coupled to the base 244a. The body 244b is provided to be movable in the third direction 16 on the base 244a. Further, the body 244b is provided to be rotatable on the base 244a. The main arm 244c is coupled to the body 244b, and provided to be movable forwardly and backwardly with respect to the body 244b. A plurality of main arms 244c is provided to be individually driven. The main arms 244c are disposed to be stacked in the state of being spaced apart from each other in the third direction 16.

The process chamber 260 performs a liquid treatment process on the substrate W. The liquid treatment process may be a cleaning process that cleans the substrate W. The process chambers 260 may have different structures depending on the type of cleaning process being performed. Alternatively, each of the process chambers 260 may have the same structure. Optionally, the process chambers 260 may be divided into a plurality of groups, such that process chambers 260 belonging to the same group may be provided with the same structure, and the process chambers 260 belonging to different groups may be provided with different structures.

The controller 900 may control the configurations of the substrate processing apparatus 10. The controller 900 may control the index module 100 and the process processing module 200. Additionally, the controller 900 may be configured to control an apparatus 300 provided in the process chamber 260.

Further, the controller 900 may include a process controller formed of a microprocessor (computer) that executes the control of the substrate processing apparatus 10, a user interface formed of a keyboard in which an operator performs a command input operation or the like in order to manage the substrate processing apparatus 10, a display for visualizing and displaying an operation situation of the substrate processing apparatus 10, and the like, and a storage unit storing a control program for executing the process executed in the substrate processing apparatus 10 under the control of the process controller or a program, that is, a treatment recipe, for executing the process in each component according to various data and processing conditions. Further, the user interface and the storage unit may be connected to the process controller. The processing recipe may be memorized in a storage medium in the storage unit, and the storage medium may be a hard disk, and may also be a portable disk, such as a CD-ROM or a DVD, or a semiconductor memory, such as a flash memory.

The apparatus 300 provided in the process chamber 260 may process the substrate W. The apparatus 300 provided in the process chamber 260 may treat the substrate W with a treatment solution or treatment gas. In the present exemplary embodiment, the present invention is described based on the case where the processing process performed by the apparatus 300 is a cleaning process that removes particles adhering to the substrate W. Such the processing process is not limited to a cleaning process, but may be applied to a variety of processes, including photography, ashing, and etching.

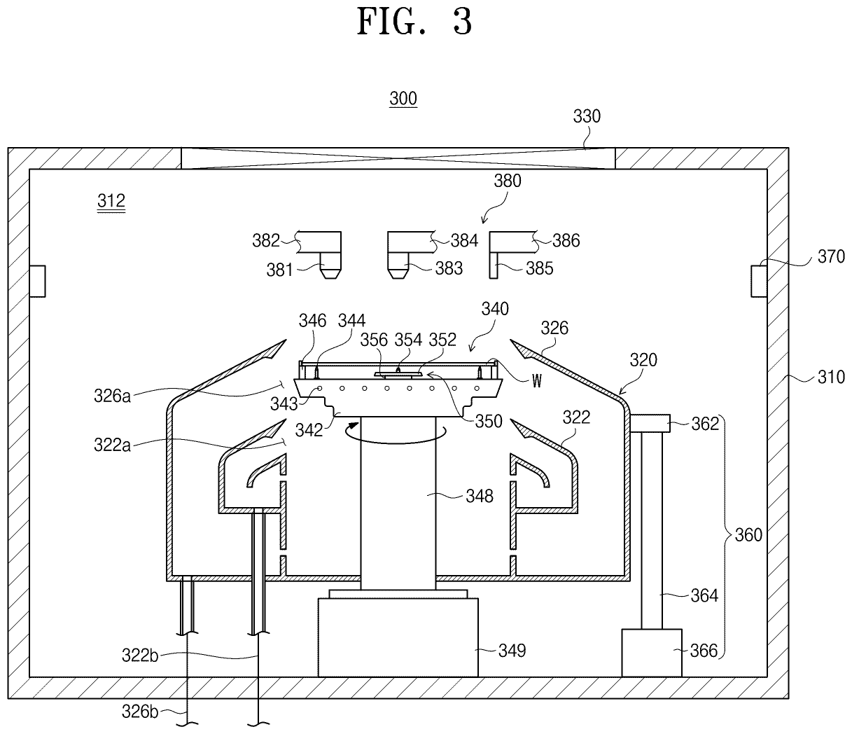

FIG. 3 is diagram illustrating the substrate processing apparatus provided in a process chamber of FIG. 2.

Referring to FIG. 3, the apparatus 300 provided in the process chamber 260 may include a housing 310, a processing container 320, a downflow unit 330, a substrate support unit 340, a lower supply unit 350, a lifting unit 360, a humidity regulating unit 370, and an upper supply unit 380.

The housing 310 may provide an interior space 312 in which the substrate W may be processed. The housing 310 may have a barrel shape to provide an interior space 312. The interior space 312 provided by the housing 310 may be a space that is hermetically sealed from the outside, or may be in some fluid communication with the outside.

The atmosphere of the interior space 312 and the atmosphere outside of the housing 310 may be regulated differently by the housing 310. For example, the humidity of the interior space 312 may be regulated by the housing 310 to be high or low. The housing 310 may also be connected to an exhaust line (not illustrated) for exhausting the atmosphere of the interior space 312.

Further, the housing 310 may have an inlet and outlet (not illustrated) through which the substrate W is loaded in or loaded out. Through the inlet and outlet formed in the housing 310, the main robot 244 of the transfer chamber 240 may load the substrate W into the interior space 312 or unload the substrate W from the interior space 312.

The processing container 320 provides a processing space within which the substrate is processed. The processing container 420 has a cylindrical shape with an open top. The processing container 320 includes an internal collection container 322 and an external collection container 326. The collection containers 322 and 326 collect different treatment solutions among the treatment solutions used for the process. The inner collection container 322 and the outer collection container 326 may each be provided in a cup shape. The inner collection container 322 may be provided in a shape that surrounds the substrate support unit 340, and the outer collection container 326 may be provided in a shape that surrounds the inner collection container 322.

The inner collection container 322 may form a first inlet 322a. Further, the inner collection container 322 and the outer collection container 326 may form a second inlet 326a. According to an example, each of the inlets 322a and 326a may be located at different heights. The first inlet 322a and the second inlet 326a may collect different types of treatment solutions.

Collection lines 322b and 326b are connected below the bottoms of the collection containers 322 and 326, respectively. The treatment solutions introduced into each of the collection containers 322 and 326 may be provided to an external treatment solution regeneration system (not illustrated) through the collection lines 422b and 426b and be reused.

The downflow unit 330 may form a downflow (DF, an example of treatment gas) in the interior space 312. By forming the downflow DF in the interior space 312, the downflow unit 330 may help the cleaning film CF described later to be uniformly formed on the substrate W.

Additionally, the downflow unit 330 may form the downflow DF by supplying dry gas into the interior space 312. The dry gas may be nitrogen gas with very low humidity, or air with very low humidity. Accordingly, the humidity of the atmosphere in the interior space 312 may be regulated by the supply of the downflow DF. As the downflow DF is supplied, the humidity in the interior space 312 may be lowered. In other words, the downflow unit 330 may function as a humidity regulating device.

The substrate support unit 340 supports the substrate W in the processing space. The substrate support unit 340 supports and rotates the substrate W during the process. The substrate support unit 340 may include a rotary chuck 342, a heater 343, a support pin 344, a chuck pin 346, a rotary shaft 348, and a rotary driver 349.

The rotary chuck 342 may be provided in a substantially circular plate shape. The rotary chuck 342 may rotate the substrate W. A bottom portion of the rotary chuck 342 may be coupled with the rotary shaft 348. The rotary shaft 348 may be a hollow shaft. The rotary shaft 348 may be coupled to the rotary driver 349, which may be a hollow motor. The rotary driver 349, which may be a hollow motor, may rotate the rotary shaft 348, and the rotary shaft 348 may rotate the rotary chuck 342. The rotary chuck 342 may have a substrate W to be treated fixedly supported by the support pin 344 and the chuck pin 346. The substrate W may be rotated by rotation of the rotary chuck 342.

Further, the rotary chuck 342 has a top surface and a bottom surface. The bottom surface has a smaller diameter than the top surface. The top surface and the bottom surface may be positioned such that their centers coincide with each other.

Within the rotary chuck 342, a heater 343 for heating the substrate W may be provided. By being provided with the heater 343, the rotary chuck 342 may function as a heating plate capable of heating the substrate W. The heater 343 may be a resistive heater that heats up by receiving power.

Alternatively, the heater 343 may be provided as a lamp that heats the substrate W by irradiating light onto the substrate W. The lamp may be provided as a lamp that irradiates infrared, visible, or ultraviolet light. When the heater 343 is provided as a lamp, at least a portion of the rotary chuck 342 (more specifically, the portion of the rotary chuck 342 facing the bottom surface of the substrate W may be provided with a material through which light may be transmitted.

A plurality of support pins 344 is provided. The support pins 344 are spaced apart at predetermined intervals on an edge of the top surface of the rotary chuck 342 and protrude upwardly from the rotary chuck 342. The support pins 344 are arranged in combination with each other to form an overall annular ring shape. The support pins 344 support the edge of the rear surface of the substrate W such that the substrate W is spaced a certain distance from the top surface of the rotary chuck 342.

A plurality of chuck pins 346 is provided. The chuck pin 346 is disposed farther from the center of the rotary chuck 342 than the support pin 344. The chuck pin 346 is provided to protrude upwardly from the top surface of the rotary chuck 342. The chuck pin 346 supports a lateral portion of the substrate W to prevent the substrate W from laterally deviating from its regular position when the rotary chuck 342 is rotated.

The chuck pin 346 is provided to be linearly movable between an outer position and an inner position along a radial direction of the rotary chuck 342. The outer position is a position farther from the center of the rotary chuck 342 relative to the inner position. When the substrate W is loaded into or unloaded from the rotary chuck 342, the chuck pin 346 is positioned in the outer position, and when performing a process on the substrate W, the chuck pin 346 is positioned in the inner position. The inner position is a position where the chuck pin 346 and the lateral portion of the substrate W are in contact with each other, and the outer position is a position where the chuck pin 346 and the substrate W are spaced apart from each other.

The lower supply unit 350 may supply a fluid for processing the substrate W to the bottom side of the substrate W. The lower supply unit 350 may supply a heated fluid for heating the substrate W. For example, the lower supply unit 350 may supply a high-temperature treatment solution, or high-temperature gas (one example of treatment gas) to heat the substrate W. For example, the lower supply unit 350 may supply high-temperature deionized water or high-temperature nitrogen gas.

The lower supply unit 350 may be provided independently of rotation of the rotary chuck 342. In other words, the lower supply unit 350 may be configured so that even when the rotary chuck 342 rotates, the lower supply unit 350 does not rotate.

The lower supply unit 350 may include a cap 52, a lower nozzle 354, and a hollow tube 356. The hollow tube 356 may be disposed within the rotary shaft 348, which may be a hollow shaft. An outer surface of the hollow tube 356 and an inner surface of the rotary shaft 348 may be provided to be spaced apart from each other. A bearing (not illustrated) may be provided between the outer surface of the hollow tube 356 and the inner surface of the rotary shaft 348 such that the hollow tube 356 does not rotate even when the rotary shaft 348 rotates.

A cap 352 may be provided at the top of the hollow tube 356. The cap 352 may prevent the fluid for processing the substrate W from entering the interior of the hollow tube 356. The lower nozzle 354 may be installed on the cap 352. A lower supply line (not illustrated) may be connected to the lower nozzle 354. The lower supply line may be configured to supply high-temperature deionized water or high-temperature nitrogen gas to the lower nozzle 354. The lower supply line may be disposed inside the hollow tube 356.

The lifting unit 360 linearly moves the processing container 320 in the up and down direction. As the processing container 320 is moved up and down, the relative height of the processing container 320 with respect to the rotary chuck 342 changes. The lifting unit 360 lowers the processing container 320 such that the rotary chuck 342 protrudes over the top of the processing container 320 when the substrate W is loaded onto or unloaded from the rotary chuck 342.

In addition, when the process is in progress, the height of the processing container 320 is adjusted so that the treatment solution may flow into the preset collection containers 322 and 326 according to the type of treatment solution supplied to the substrate W. The lifting unit 360 includes a bracket 362, a lifting shaft 364, and a lifting driver 366. The bracket 362 is fixedly mounted to an exterior wall of the processing container 320, and the lift shaft 364 is fixedly coupled to the bracket 362 that is moved up and down by the lift driver 366. Optionally, the lifting unit 360 may move the rotary chuck 342 in the up and down direction.

A humidification device 370 may regulate the humidity of the interior space 312. The humidification device 370 may supply humidified air (WA, an example of the treatment gas) into the interior space 312 to regulate the atmosphere of the interior space 312. The humidified air WA may be water vapor. As the humidified air WA is supplied to the interior space 312, the humidity of the interior space 312 may increase. The humidified device 370 may function as a humidity regulating device to regulate the humidity of the interior space 312. The humidification regulating unit 370 may be attached to an inner wall of the housing 310. A plurality of humidification regulating units 370 may be provided as needed.

The upper supply unit 380 may supply the fluid for processing the substrate W. The upper supply unit 380 may supply a coating liquid CL, a rinse liquid RL, and dry gas DG to the substrate W.

The upper supply unit 380 may include a first upper nozzle 381, a first arm 382, a second upper nozzle 383, a second arm 384, a drying nozzle 385, and a third arm 386.

The first upper nozzle 381 is coupled to the first arm 382 and may be moved between a position facing the center of the substrate W and a position away from the top side of the substrate W. The second upper nozzle 383 is coupled to the second arm 384 and may be moved between a position facing the center of the substrate W and a position away from the top side of the substrate W. The drying nozzle 385 is coupled to the third arm 386 and may be moved between a position facing the center of the substrate W and a position away from the top side of the substrate W.

In the example described above, the present invention has been described based on the case where the first upper nozzle 381, the second upper nozzle 83, and the drying nozzle 385 are each coupled to a separate arm as an example, but is not limited thereto. For example, the first upper nozzle 381, the second upper nozzle 83, and the drying nozzle 385 may all be coupled to the same arm, or some of the first upper nozzle 381, the second upper nozzle 83, and the drying nozzle 385 may be coupled to the same arm and others to separate arms.

The first upper nozzle 381 may supply the coating liquid CL. The coating liquid CL may be a liquid containing a first component, a second component, and a volatile component. The coating liquid CL may be solidified or cured as described below to phase change into the cleaning film CF described herein. The volatile component contained in the coating liquid CL may contain alcohol. The volatile component may be an alcohol-based solvent. For example, the volatile component may be an alcohol-based solvent, such as a mixture of butanol and methylisobutylcarbinol. The first component may be organic acid. The second component may be a polymer. For example, the second component may be styrene. The first component may have higher solubility in moisture around the substrate W compared to the second component.

The second upper nozzle 383 may supply the rinse liquid RL. The rinse liquid RL may be provided as a liquid capable of dissolving the cleaning film CF. The rinse liquid RL may be isopropyl alcohol. The rinse liquid RL may also be referred to as a dissolving liquid that dissolves the cleaning film CF, or a removal liquid that removes the cleaning film CF from the substrate W.

The drying nozzle 385 may supply the dry gas DG. The dry gas DG may be dried inert gas. For example, the dry gas DG may be nitrogen gas with very low humidity, or air with very low humidity.

Hereinafter, a substrate processing method according to an exemplary embodiment of the present invention will be described in detail. The controller 900 may control configurations of the substrate processing apparatus 300 to enable the substrate processing apparatus 300 to perform the substrate processing methods described herein.

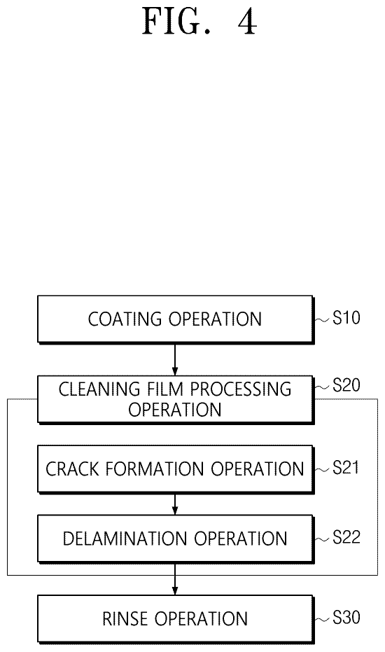

FIG. 4 is a flow chart illustrating a substrate processing method according to an exemplary embodiment of the present invention.

Referring to FIG. 4, a substrate processing method according to an exemplary embodiment of the present invention may include a coating operation S10, a cleaning film processing operation S20, and a rinse operation S30. Although not illustrated, a drying operation to dry the substrate W may optionally be performed after the rinse operation S30. The coating operation S10, the cleaning film processing operation S20, and the rinse operation S30 may be performed sequentially. Further, the cleaning film processing operation S20 may include a crack formation operation S21 and a delamination operation S22. The cleaning film processing operation S20 may crack the cleaning film CF to form film flakes CFSLs, volatilize the volatile components contained in the film flakes CFSLs, and delaminate the film flakes CFSLs from the top surface of the substrate W.

The crack formation operation S21 and the delamination operation S22 may be performed sequentially. Alternatively, the crack formation operation S21 and the delamination operation S22 may be performed simultaneously. Furthermore, the cleaning film processing operation S20 may be performed in a sequence in which the crack formation operation S21 starts, the delamination operation S22 starts, the crack formation operation S21 ends, and the delamination operation S22 ends.

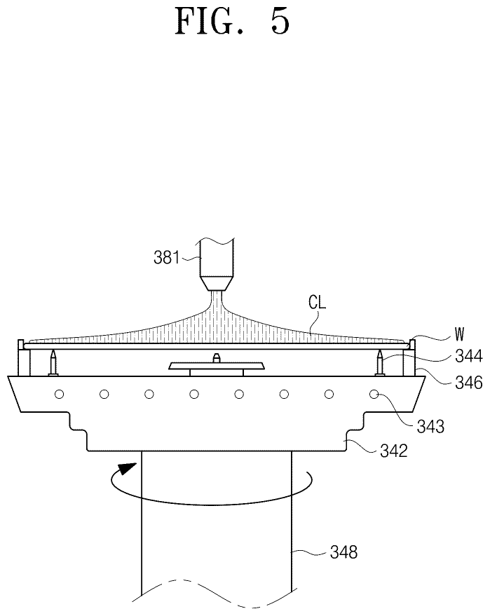

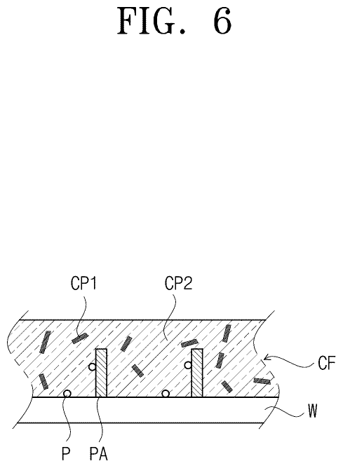

FIG. 5 is a diagram illustrating the substrate processing apparatus performing the coating operation of FIG. 4, and FIG. 6 is an enlarged view of the portion of the top surface of the substrate when performing the coating operation of FIG. 4.

Referring to FIGS. 5 and 6, in the coating operation S10, a coating liquid CL may be supplied to the top surface of the rotating substrate W. In the coating operation S10, the coating liquid CL may be supplied to the center of the top surface of the rotating substrate W, and the supplied coating liquid CL may spread over the entire top surface of the substrate W while being diffused to the edge region as the substrate W rotates.

After the coating liquid CL is spread across the entire surface of the substrate W, the first upper nozzle 381 may stop supplying the coating liquid CL. The substrate W is then rotated at a relatively high speed (e.g., a speed exceeding 1000 RPM), which may volatilize the volatile components contained in the coating liquid CL. As the volatile components in the coating liquid CL are volatilized, the coating liquid CL may be solidified or cured and become a phase change. More specifically, as at least some of the volatile components included in the coating liquid CL are volatilized, the first component (organic acid) and the second component (polymer) included in the solvent of the coating liquid CL may form a first solid CP1 and a second solid CP2, respectively. That is, as at least some of the volatile components included in the coating liquid CL are volatilized, the coating liquid CL is phase changed, and the phase-changed coating liquid CL may form a cleaning film CF containing the first solid CP1 and the second solid CP2.

The coating operation S10 may include volatilizing the volatile components of the coating liquid CL, but may not volatilize all of the volatile components of the coating liquid CL. For example, after the coating operation S10 is completed, the cleaning film CF may contain about 20% of the volatile components.

Further, when the coating operation S10 is performed, the humidity of the interior space 312 may be regulated to about 40%. The humidity of the interior space 312 may be regulated by the downflow unit 330 and/or the humidification regulating unit 370.

After the coating operation S10 is performed, the coating liquid CL may be solidified or cured in the form of a cleaning film CF. The cleaning film CF may capture particles P adhering to the top surface of the substrate W and/or particles P adhering to the pattern PA formed on the substrate W during the process of solidification or curing.

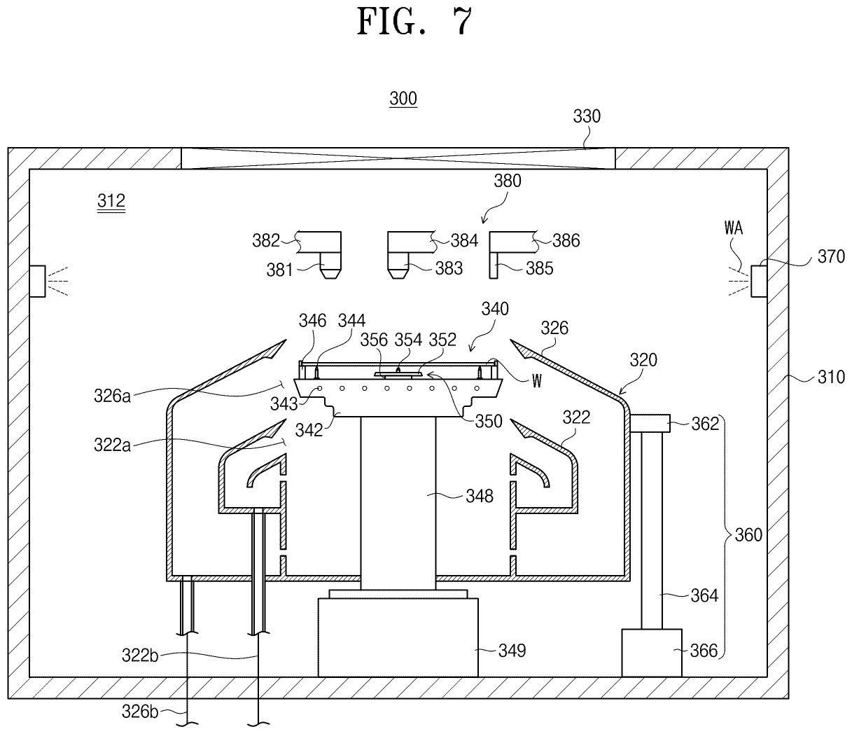

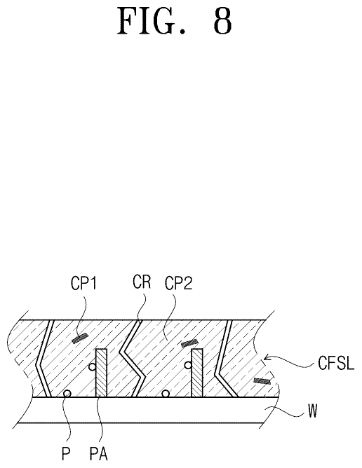

FIG. 7 is a diagram illustrating the substrate processing apparatus performing the crack formation operation of FIG. 4, and FIG. 8 is an enlarged view of the portion of the top surface of the substrate when performing the crack formation operation of FIG. 4.

Referring to FIGS. 7 and 8, the crack formation operation S21 may include forming (generating) cracks CRs in the cleaning film CF formed on the substrate W. The substrate W may not be rotated during the crack formation operation S21. During the crack formation operation S21, the humidification regulating unit 370 may supply humidified air WA to the interior space 312 to increase the humidity of the interior space 312. In the crack formation operation S21, by increasing the humidity of the interior space 312, the humidity of the space above the substrate W may be increased. In the crack formation operation S21, the humidity of the interior space 312 may be increased to about 50%. Since the cleaning film CF is very sensitive to moisture, the increased humidity of the interior space 312 may be sufficient to cause cracks to form.

More specifically, the first solid CP1 formed of the first component of the cleaning film CF is very sensitive to moisture around the substrate W, and as the first solid CP1 is largely dissolved by moisture, cracks CR may be generated. In addition, the second solid CP2 formed of the second component is less soluble or practically very little soluble in moisture, so that the second solid CP2 may remain in a particle captured state.

As the crack CR is generated in the cleaning film CF, the cleaning film CF may split, and as the cleaning film CF splits, film flakes CFSLs may form.

Furthermore, because the cracks CR are generated through a vapor phase fluid rather than a liquid phase fluid, the cleaning film CF may be formed of materials that may be more sensitive to moisture. When the generation of the crack CR is implemented through the liquid phase fluid, there is a high risk of total dissolution of the cleaning film CF by the liquid phase fluid, but since the present invention implements the generation of the CR through the gas phase fluid, it is possible to configure the cleaning film CF from a material that may be more sensitive to moisture. For example, the proportion of the first component that the coating liquid CL includes may be increased. In this case, the time taken for generating the crack CR may be effectively reduced.

Furthermore, in one exemplary embodiment of the present invention, the substrate W may not be rotated in the crack formation operation S21, as the increased humidity in the interior space 312 may be sufficient to cause cracks to form. When the substrate W is rotated in the crack formation operation S21, the film flakes CFSLs may be moved laterally by the centrifugal force of the substrate W, and in this case, the film flakes CFSLs may re-adhere.

When the film flakes CFSLs re-adhere, it may be difficult for the dry gas DG supplied in the delamination operation S22 described later to penetrate into the space between the film flakes CFSLs. Furthermore, the portion where the film flakes CFSLs are delaminated from the substrate W may become small. Therefore, in the crack formation operation S21 of the present invention, the film flakes CFSLs may be formed through the gas phase fluid without rotating the substrate W.

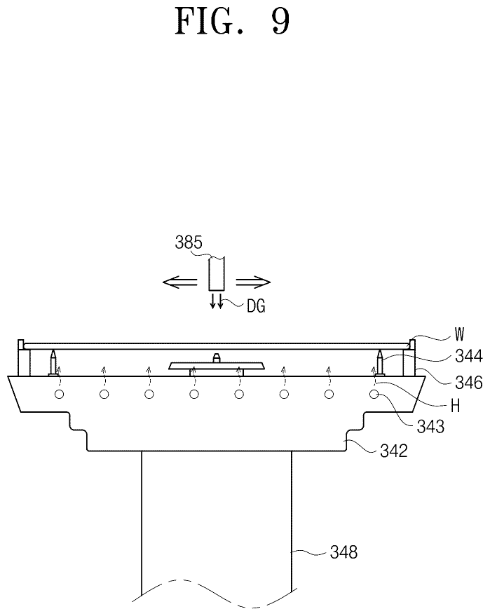

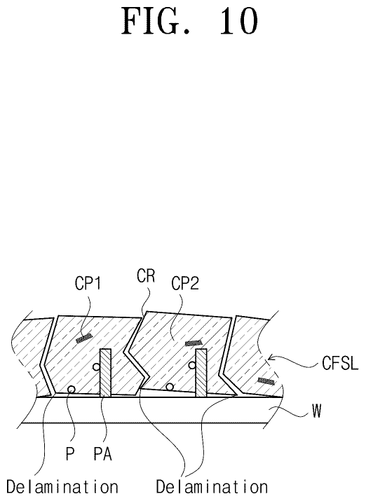

FIG. 9 is a diagram illustrating the substrate processing apparatus performing a delamination operation of FIG. 4, and FIG. 10 is an enlarged view of a portion of the top surface of the substrate when performing the delamination operation of FIG. 4.

Referring to FIGS. 9 and 10, the delamination operation S22 may include reducing the humidity of the space above the substrate W. In addition, the substrate W may be heated in the delamination operation S22. In the delamination operation S22, the lower portion of the film flake CFSL may be delaminated from the top surface of the substrate W by volatilizing the volatile components that the film flake CFSL may contain.

As described above, when the coating operation S10 is terminated, the cleaning film CF contains about 20% volatile components. In the delamination operation S22, the remaining volatile components in the film flakes CFSLs may be volatilized by reducing the humidity of the space above the substrate W or heating the substrate W. In this case, further solidification or curing of the film flakes CFSLs may result in warping of the film flakes CFSLs, which may cause the lower portion of the film flake CFSL to be delaminated from the top surface of the substrate W.

The delamination operation S22 may be accomplished by supplying, the drying nozzle 385, dry gas DG to the top surface of the substrate W, or generating, by the heater 343, heat to heat the substrate W. Also, the delamination operation S22 may not involve rotating the substrate W, as was the case with the crack formation operation S21.

As described above, since the cleaning film processing operation S20 treats the cleaning film CF without rotating the substrate W, damage to the pattern PA formed on the substrate W may be minimized. Furthermore, since the cleaning film processing operation S20 does not use deionized water to delaminate the film flake CFSL from the top surface of the substrate W, the film flake CFSL may be effectively delaminated from the top surface of the substrate W regardless of whether the surface of the substrate W is hydrophilized or hydrophobized.

In addition, since the film flake CFSL is not formed using a liquid phase fluid, the cleaning film CF formed on the substrate W may be formed with a material that is more sensitive to moisture, and accordingly, the time required to form the film flake CFSL from the cleaning film CF and to delaminate the formed film flake CFSL from the top surface of the substrate W may be minimized.

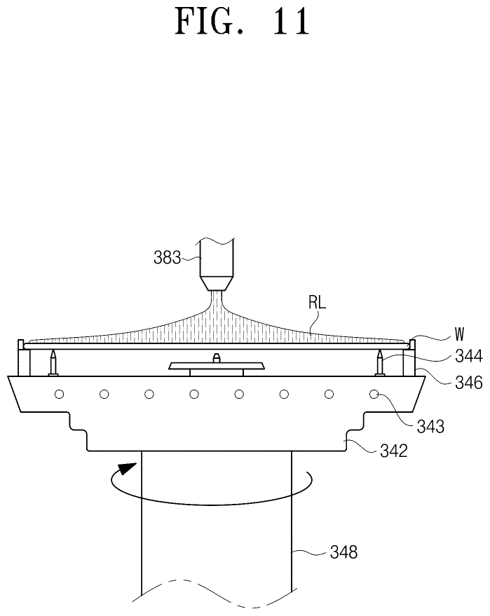

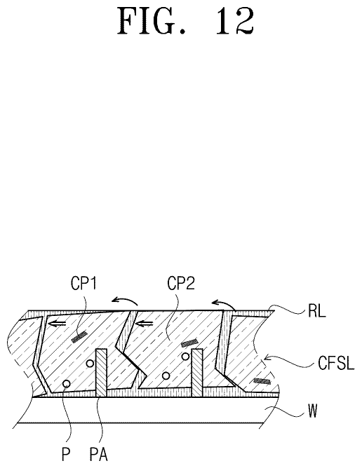

FIG. 11 is a diagram illustrating the substrate processing apparatus performing the rinse operation of FIG. 4, and FIG. 12 is an enlarged view of a portion of the top surface of the substrate when performing the rinse operation of FIG. 4.

Referring to FIGS. 11 and 12, the rinse operation S30 according to the exemplary embodiment of the present invention may include supplying the rotating substrate W with a rinse liquid RL. The rinse liquid RL may be a liquid capable of dissolving or removing the film flakes CFSLs. The rinse liquid RL may be isopropyl alcohol (IPA). Before the rinsing operation S30 is performed, the film flakes CFSLs may be in a state where the lower ends thereof are separated from the top surface of the substrate W by the cleaning film processing operation S20. Accordingly, the rinse liquid RL penetrates between the film flakes CFSLs, and when the substrate W is rotated, the film flakes CFSLs may be subjected to a large moment due to the centrifugal force of the rinse liquid RL. Therefore, even when the substrate W is rotated at a relatively low speed (e.g., a speed of about 500 to 1000 RPM) in the rinse operation S30, the film flakes CFSLs may be effectively removed. Since the film flakes CFSLs are effectively removed even when the substrate W is rotated at a relatively low speed, damage to the pattern PA formed on the substrate W may be minimized.

Furthermore, in the case of processing the cleaning film CF using liquid deionized water, it takes a certain amount of time for the deionized water on the substrate W to be replaced by the isopropyl alcohol supplied in the rinse operation S30, but in the exemplary embodiment of the present invention, the rinse operation S30 is performed by supplying isopropyl alcohol immediately without the need to take time to replace the deionized water, which has the advantage of further reducing the time required to treat the substrate W.

In the examples described above, the present invention has been described based on the case where the humidification regulating unit 370 is attached to the inner wall of the housing 310 as an example, but is not limited thereto. For example, the humidification regulating unit 370 may be provided in the form of a nozzle, and may be provided in the form which sprays humidified air WA from the portion above of the substrate W onto the top surface of the substrate W.

In the example described above, the present invention has been described based on the case where the humidity of the interior space 312 rises to about 50% in the crack formation operation S21 as an example, but this is not limited to this example. For example, the humidity of the interior space 312 may rise to about 100% in the crack formation operation S21.

In the examples described above, the present invention has been described based on the case where the coating liquid CL includes the first component, the second component, and the volatile component as an example, but is not limited thereto. For example, the coating liquid CL may be transformed into a variety of liquids that include a solute, and a solvent that is a volatile component. The solute may be variously modified with known polymers that are solidified or cured as the volatile component volatilizes, but may be subject to some cracking by moisture.

In the examples described above, the present invention has been described based on the case where the humidity of the interior space 312 is regulated differently in the coating operation S10 and the crack formation operation S21 as an example, but is not limited to this. For example, in the coating operation S10 and the crack formation operation S20, the humidity of the interior space 312, more specifically, the space above the substrate W, may be kept the same, such as about 50%. In this case, in the coating operation S10, the substrate W is rotated, so that the volatile components of the coating liquid CL may volatilize despite the 50% humidity, and in the crack formation operation S21, the substrate W is not rotated, so that the volatile components no longer volatilize, and cracks CR may be formed in the cleaning film CF by the 50% humidity. The humidity of about 50% may be the humidity in a typical room environment.

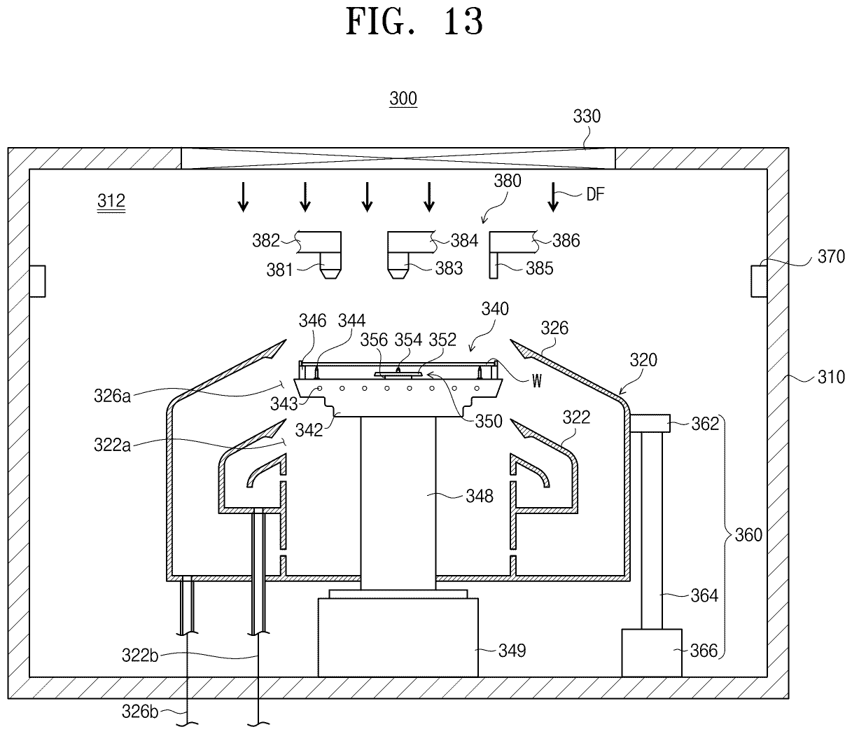

In the example described above, the present invention has been described based on the case where the drying nozzle 385 supplies the dry gas DG in the delamination operation S22 to reduce the humidity of the space above the substrate W as an example, but is not limited thereto. For example, as illustrated in FIG. 13, the downflow unit 330 may supply dry gas to form the downflow DF to reduce the humidity of the top space of the substrate W.

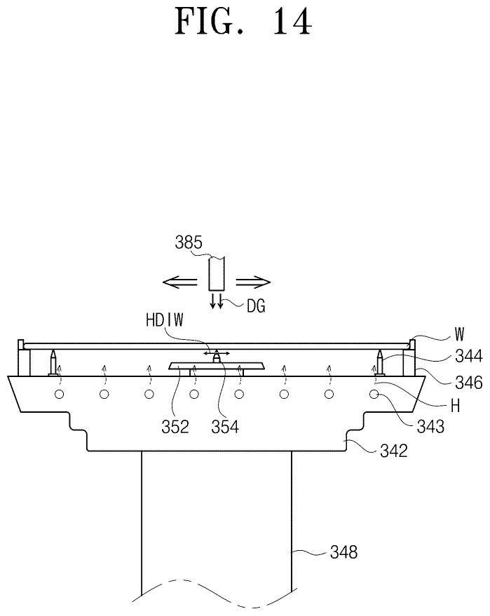

In the example described above, the present invention has been described based on the case where the substrate W is heated by the heater 343 when performing the delamination operation S22 as an example, but is not limited thereto. For example, the lower supply unit 350 may also heat the substrate W by supplying high-temperature deionized water HDIW to the bottom surface of the substrate W, as illustrated in FIG. 14.

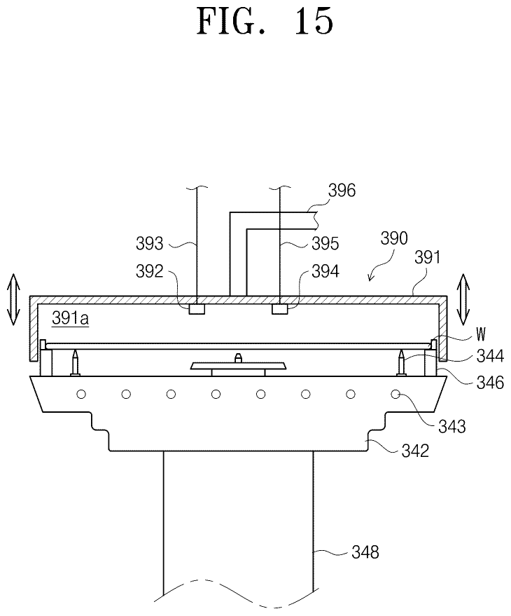

FIG. 15 is a diagram illustrating a substrate processing apparatus according to another exemplary embodiment of the present invention.

Referring to FIG. 15, a substrate processing apparatus 300 according to an exemplary embodiment of the present invention may further include a cleaning film processing unit 390. The cleaning film processing unit 390 may be a unit for performing the cleaning film processing operation S20 described above.

The cleaning film processing unit 390 may include a cover 391, a humidified air outlet 392, a humidified air supply line 393, a dry gas outlet 394, a dry gas supply line 395, and a cover arm 396. The humidified air outlet 392 and the humidified air supply line 393 may be other examples of the humidifying device 370 described above.

The cover 391 may have the shape of a cover with an open bottom. The cover 391 may be repositioned by the cover arm 396 in an up-down direction and a left-right direction. When the cleaning film processing operation S20 is initiated, the cover 391 may cover the space above the substrate W. The cover 391 may cover an upper space 391a of the substrate W.

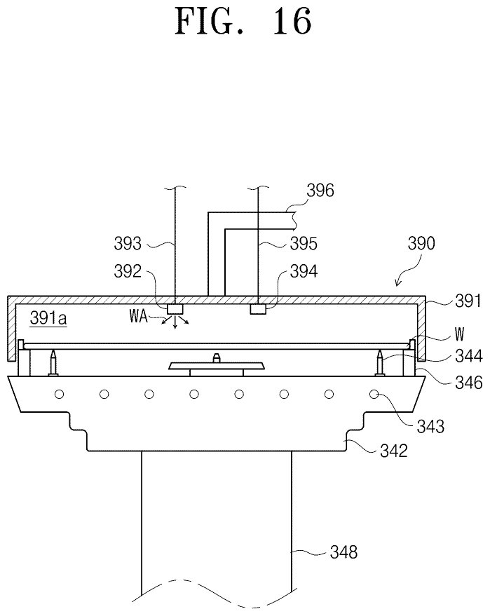

Then, as illustrated in FIG. 16, the humidified air outlet 392 may receive humidified air WA from the humidified air supply line 393 and discharge the humidified air WA into the upper space 391a. Accordingly, the humidity in the upper space 391a may increase, which may cause cracks to form in the cleaning film CF.

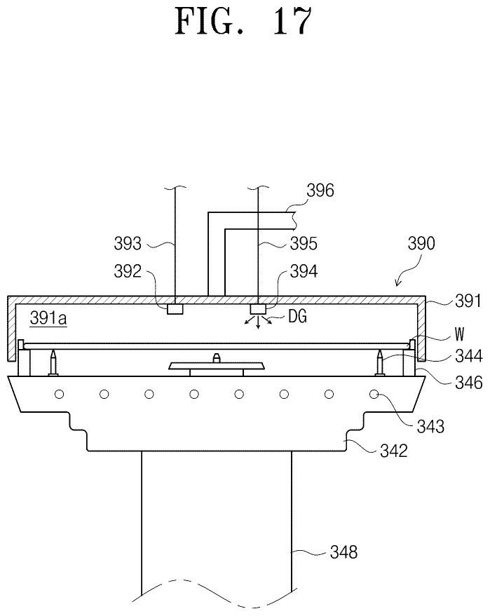

Then, as illustrated in FIG. 17, the dry gas outlet 394 may receive dry gas DG from the dry gas supply line 395 to supply the dry gas DG to the upper space 391a. Accordingly, the humidity in the upper space 391a may be lowered to allow the film flakes CFSLs to be delaminated from the top surface of the substrate W.

According to another exemplary embodiment of the present invention, the volume of the upper space 391a of the substrate W is reduced by the cover 391 so that a supply of the humidified air WA and the dry gas DG may be provided. Accordingly, the humidity transition in the upper space 391a may be accomplished very quickly. Thus, the substrate processing apparatus 300 according to another exemplary embodiment of the present invention may effectively shorten the time required to perform the cleaning film processing operation S20.

In the above-described example, the present invention has been described based on the case where the rinse liquid RL is isopropyl alcohol as an example, but it is not limited thereto, and the rinse liquid RL may be ammonia water, an aqueous solution of ammonium hydroxide such as tetramethyl ammonium hydroxide, an aqueous solution of choline, an alkaline developer, and the like.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

1. A method of processing a substrate, the method comprising:
a coating operation of supplying a coating liquid containing a volatile component to a top surface of the substrate to form a cleaning film; and
a cleaning film processing operation of processing the cleaning film,
wherein the cleaning film processing operation includes:
a crack formation operation of generating a crack in the cleaning film formed on the substrate to form film flakes; and
a delamination operation of delaminating the film flakes from the top surface of the substrate by volatilizing the volatile component contained in the film flake.

2. The method of claim 1, wherein the crack formation operation includes spraying humidified air to increase humidity of a space above the substrate.

3. The method of claim 1, wherein in the coating operation and the crack formation operation, the humidity of the space above the substrate is kept the same,
the coating operation includes rotating the substrate, and
the crack formation operation includes stopping the rotation of the substrate.

4. The method of claim 1, wherein the delamination operation includes heating the substrate to volatilize the volatile component contained in the film flake.

5. The method of claim 4, wherein the heating of the substrate is accomplished by a heater provided in a chuck supporting the substrate.

6. The method of claim 4, wherein the heating of the substrate is accomplished by supplying heated pure water to a bottom surface of the substrate.

7. The method of claim 1, wherein the delamination operation includes spraying dry air to reduce humidity in the space above the substrate to volatilize the volatile component contained in the film flake.

8. The method of claim 7, wherein the spraying of the dry air is accomplished by supplying, by a drying nozzle, dry gas from an upper side of the substrate.

9. The method of claim 7, wherein the spraying of the dry gas is accomplished by forming a dried downflow in the interior space by a downflow unit coupled to a housing providing an interior space in which the substrate is processed.

10. The method of claim 1, wherein in the coating operation, the substrate is in a rotating state in which the substrate is rotated, and
in the cleaning film processing operation, the substrate is in a non-rotating state in which the substrate is not rotated.

11. The method of claim 1, further comprising:
after the cleaning film processing operation, a rinsing operation of supplying a rinse liquid to the rotating substrate while dissolving the film flakes.

12. The method of claim 11, wherein in the rinse operation, the substrate is rotated at a speed of 500 to 1000 RPM.

13. The method of claim 11, wherein the rinse liquid is isopropyl alcohol.

14. The method of claim 1, wherein the cleaning film processing operation is performed in a state where the space above the substrate is covered by a cover disposed on an upper side of the substrate.

15. A manufacturing method comprising:
a coating operation of supplying a coating liquid containing a volatile component, a first component, and a second component to a top surface of a rotating substrate to form a cleaning film; and
a crack formation operation of regulating humidity around the non-rotating substrate to generate cracks in the cleaning film and form film flakes.

16. The manufacturing method of claim 15, wherein the crack formation operation includes regulating humidity in a space above the substrate to be larger than in the coating operation.

17. The manufacturing method of claim 15, wherein the first component is a component that is more soluble in moisture surrounding the substrate than the second component.

18. The manufacturing method of claim 17, wherein the first component is organic acid and the second component is a polymer.

19. The manufacturing method of claim 15, further comprising:
a delamination operation of delaminating the film flakes from the top surface of the substrate by volatilizing the volatile component contained in the film flake.

20. (canceled)
